(19) United States
(12) Patent Application Publication
(10) Pub. No.: US 2023/0273295 A1
(43) Pub. Date: Aug. 31, 2023

(54) IN-VEHICLE RADAR DEVICE

(71) Applicant: Mitsubishi Electric Corporation, Tokyo (JP)

(72) Inventors: Takashi OHARA, Tokyo (JP); Kazuhisa TAMURA, Tokyo (JP)

(73) Assignee: Mitsubishi Electric Corporation, Tokyo (JP)

(21) Appl. No.: 18/040,026

(22) PCT Filed: Dec. 28, 2020
(86) PCT No.: PCT/JP2020/049151

§ 371 Date: Jan. 31, 2023

(51) Int. Cl. G01S 7/02; H05K 5/03; H05K 7/20

(52) U.S. Cl. CPC G01S 7/027; H05K 5/03; H05K 7/20154

(57) ABSTRACT

This in-vehicle radar device includes: a conductive heat sink; a first cover covering a first-direction side of the heat sink; a second cover covering a second-direction side of the heat sink and connected to the first cover; a first circuit board including a first board, a first electronic component, a first ground pattern, and an antenna portion, stored between the heat sink and the first cover, and contacting with the heat sink; a conductive inner cover contacting with the first cover and the first circuit board; and an elastic member pressing the heat sink, the first circuit board, and the inner cover to the first cover. The first ground pattern contacts with and is electrically connected to one or both of the heat sink and the inner cover. A distance between the antenna portion and the first cover is equal to a thickness of the inner cover.

### TECHNICAL FIELD

The present disclosure relates to an in-vehicle radar device.

### BACKGROUND ART

An in-vehicle radar device is a device that transmits radio waves to an object around a vehicle equipped with the in-vehicle radar device and receives a reflection wave reflected by the object. The in-vehicle radar device measures the distance between the object and the vehicle equipped with the in-vehicle radar device, or the like. The in-vehicle radar device has a board mounted with a plurality of components and an antenna for transmitting/receiving radio waves, for example. The in-vehicle radar device is located in an equipment environment space such as a surrounding area of a rear confirmation mirror in a vehicle compartment or the inside of a bumper. The in-vehicle radar device is formed by a plurality of boards in accordance with the radar size requirements and the areas of board mounting components based on the equipment environment space, and the plurality of boards are stored in a housing.

In such an in-vehicle radar device, the radar function might be reduced or components might be damaged, due to the influences of the environmental temperature at the equipment position, heat generation of board components, a vibration load from a road surface during vehicle traveling, and the like. In addition, in such an in-vehicle radar device, if a component having a low withstand capacity on the board receives unnecessary radio waves from outside, the component might erroneously operate, leading to performance abnormality or stop of operation. Further, if the contact resistance value at a contact part between a ground pattern of the board and a conductive member is changed, variations arise in the shield characteristics.

In order to solve the above problems, the following structures are disclosed (see, for example, Patent Document 1). For improving the shield characteristics of the board against unnecessary radio waves, a board is covered by a conductive member such as a metal that blocks unnecessary radio waves; for reducing the influence of heat inside the device, a metal part that has high thermal conductivity and efficiently transfers heat to the outside air is used for a housing; and for improving vibration resistance, a ground pattern of the board and a conductive member are fastened with a plurality of metal parts so as to be electrically connected.

In general, in such an in-vehicle radar device, if the distance between an antenna for transmitting/receiving radio waves and a radio wave passing portion of a cover covering the antenna varies, a beam pattern changes, and due to disorder of the beam pattern, variations arise in radar performance such as ranging accuracy and angle measurement accuracy. Therefore, in order to reduce variations in the distance between the antenna and the radio wave passing portion of the cover, it is necessary to enhance dimension accuracy of components interposed between the antenna surface and a radio wave passing surface of the cover. In order to enhance the dimension accuracy of components, a plurality of working processes for managing dimension accuracy and an inspection process such as component sorting are needed.

### CITATION LIST

### Patent Document

Patent Document 1: Japanese Laid-Open Patent Publication No. 2001-42025

### SUMMARY OF THE INVENTION

### Problems to be Solved by the Invention

In the in-vehicle radar device in Patent Document 1, since the entirety of control means is covered by the housing and electromagnetic wave transmission/reception means at the same potential, the radar performance can be prevented from being deteriorated due to entering water and unnecessary electromagnetic waves. However, in order to ensure stable contact pressure and conductivity at a contact part between the ground pattern of the board and another conductive member, a process for managing screwing torque for a plurality of components is needed, thus having a problem that stable electric connection between the ground pattern of the board and the conductive member cannot be easily ensured. In addition, there is no consideration for reducing variations in accuracy of the distance between the antenna and the cover through which radio waves pass, and therefore the distance between the antenna and the cover readily changes through expansion/contraction of a plurality of components due to the environmental temperature, thus having a problem that variations arise in the radar performance.

Accordingly, an object of the present disclosure is to provide an in-vehicle radar device in which stable electric connection between a ground pattern of a board and a member having conductivity is easily ensured and variations in the radar performance are reduced.

### Solution to the Problems

An in-vehicle radar device according to the present disclosure includes: a conductive heat sink which includes a plate-shaped portion formed in a flat-plate shape, and of which an outer peripheral surface is at least partially exposed to outside; a first cover which allows radio waves to pass therethrough, where a normal direction of one surface of the plate-shaped portion is defined as a first direction and a normal direction of another surface of the plate-shaped portion is defined as a second direction, the first cover covering the first-direction side of the heat sink; a second cover covering the second-direction side of the heat sink and connected to the first cover; a first circuit board including a plate-shaped first board, a first electronic component and a first ground pattern provided at one or both of a surface on the first-direction side and a surface on the second-direction side of the first board, and a plate-shaped antenna portion formed at the surface on the first-direction side of the first board, the first circuit board being stored in a first space formed between the heat sink and the first cover, such that the surface on the second-direction side of the first board contacts with the heat sink; a conductive inner cover formed in a plate shape and having a through portion at a part opposed to the antenna portion, the inner cover being stored in the first space, such that a surface thereof on the first-direction side contacts with the first cover and a surface thereof on the second-direction side contacts with at least a part of the surface on the first-direction side of the first circuit board; and an elastic member fixed to the first-direction side of the second cover and pressing the heat sink, the first circuit board, and the inner cover to the first cover, so that the first circuit board is held between the heat sink and the inner cover. The first ground pattern of the first circuit board contacts with and is electrically connected to one or both of the heat sink and the inner cover. A distance between the antenna portion and the first cover is equal to a thickness of the inner cover.

### Effect of the Invention

The in-vehicle radar device according to the present disclosure includes the elastic member fixed to the first-direction side of the second cover and pressing the heat sink, the first circuit board, and the inner cover to the first cover, so that the first circuit board is held between the heat sink and the inner cover, and the first ground pattern of the first circuit board is pressed by the elastic member so as to contact with and be electrically connected to one or both of the conductive heat sink and the conductive inner cover. Thus, it is possible to easily ensure stable electric connection between the first ground pattern of the first circuit board and the member having conductivity. In addition, since the distance between the antenna portion and the first cover is equal to the thickness of the inner cover pressed by the elastic member, variations in accuracy of the distance between the antenna portion and the first cover are reduced, and the distance between the antenna portion and the first cover does not readily change. Thus, variations in the radar performance can be reduced.

### BRIEF DESCRIPTION OF THE DRAWINGS

FIG. 1 is a perspective view showing the outer appearance of an in-vehicle radar device according to embodiment 1.

FIG. 2 is an exploded perspective view of the in-vehicle radar device according to embodiment 1.

FIG. 3 is a plan view of the in-vehicle radar device according to embodiment 1.

FIG. 4 is a sectional view of the in-vehicle radar device taken at an A-A cross-section position in FIG. 3.

FIG. 5 is a plan view of a first circuit board of the in-vehicle radar device according to embodiment 1.

FIG. 6 is a plan view of another first circuit board of the in-vehicle radar device according to embodiment 1.

FIG. 7 is a plan view of another first circuit board of the in-vehicle radar device according to embodiment 1.

FIG. 8 is a plan view of another first circuit board of the in-vehicle radar device according to embodiment 1.

FIG. 9 is a sectional view of another in-vehicle radar device taken at the A-A cross-section position in FIG. 3.

FIG. 10 is a major part sectional view of an in-vehicle radar device according to embodiment 2.

FIG. 11 is a perspective view showing a protrusion of the in-vehicle radar device according to embodiment 2.

FIG. 12 is a sectional view of an in-vehicle radar device according to embodiment 3.

FIG. 13 is a sectional view of an in-vehicle radar device according to embodiment 4.

FIG. 14 is a plan view of an in-vehicle radar device according to embodiment 5.

FIG. 15 is a plan view of another in-vehicle radar device according to embodiment 5.

### DESCRIPTION OF EMBODIMENTS

Hereinafter, an in-vehicle radar device according to embodiments of the present disclosure will be described with reference to the drawings. In the drawings, the same or corresponding members and parts are denoted by the same reference characters, to give description.

### Embodiment 1

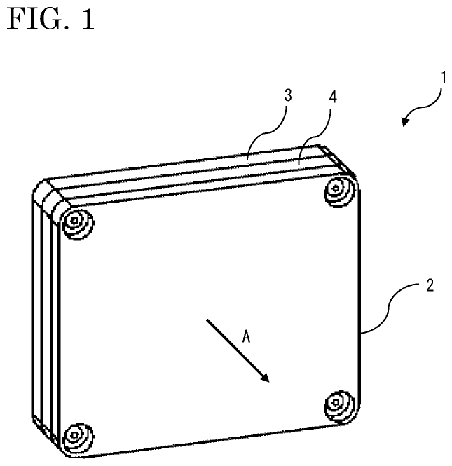

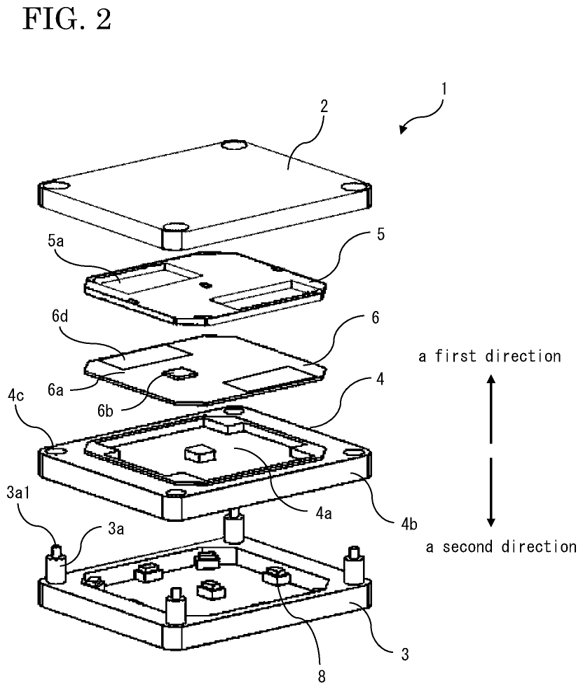

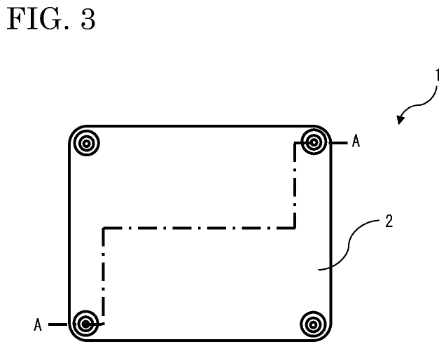

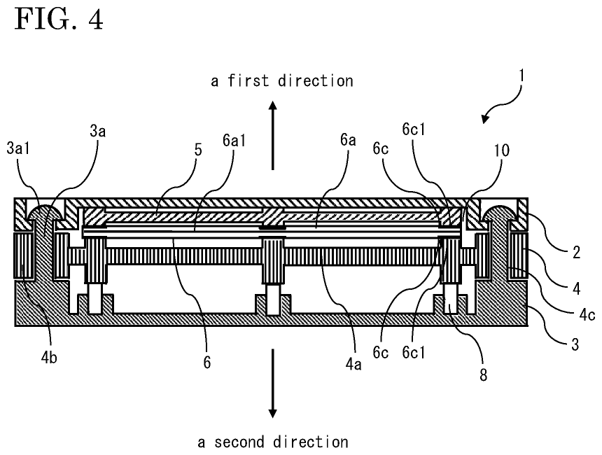

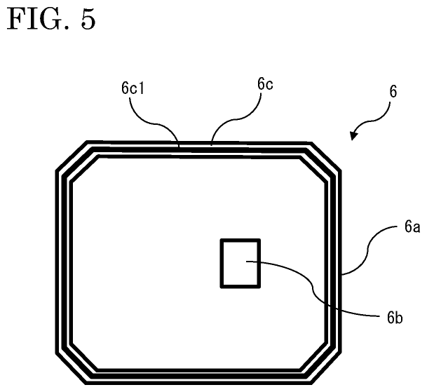

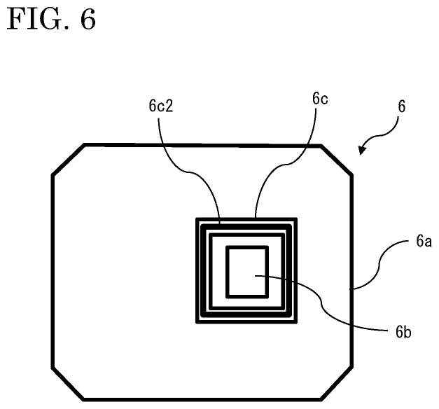

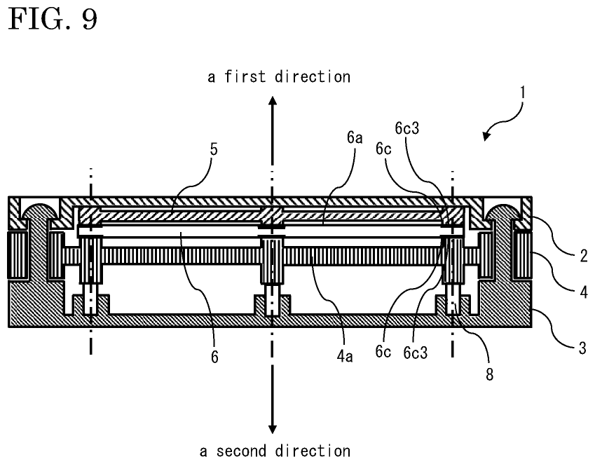

FIG. 1 is a perspective view showing the outer appearance of an in-vehicle radar device 1 according to embodiment 1. FIG. 2 is an exploded perspective view of the in-vehicle radar device 1. FIG. 3 is a plan view on a first cover 2 side of the in-vehicle radar device 1. FIG. 4 is a sectional view of the in-vehicle radar device 1 taken at an A-A cross-section position in FIG. 3. FIG. 5 is a plan view of a first circuit board 6 of the in-vehicle radar device 1. FIG. 6 to FIG. 8 are plan views of other first circuit boards 6 of the in-vehicle radar device 1 according to embodiment 1. FIG. 9 is a sectional view of another in-vehicle radar device 1 taken at the A-A cross-section position in FIG. 3. The in-vehicle radar device 1 is a device that transmits radio waves to an object around a vehicle equipped with the in-vehicle radar device 1 and receives a reflection wave reflected by the object. The in-vehicle radar device 1 measures the distance between the device-equipped vehicle and the object, or the like.

<In-Vehicle Radar Device 1>

As shown in FIG. 1, the in-vehicle radar device 1 includes a conductive heat sink 4 of which the outer peripheral surface is at least partially exposed to outside, a first cover 2 which allows radio waves to pass therethrough, and a second cover 3 connected to the first cover 2. In the present embodiment, components composing the in-vehicle radar device 1 are stored in a first space 10 (not shown in FIG. 1) formed between the heat sink 4 and the first cover 2. Since a part of the heat sink 4 is exposed to outside, heat of components stored inside the in-vehicle radar device 1 can be efficiently dissipated to the outside air. The heat sink 4 shown in FIG. 1 is exposed to outside over the entire outer peripheral surface. However, without limitation thereto, a part of the outer peripheral surface may be covered by the first cover 2 and the second cover 3. The in-vehicle radar device 1 transmits radio waves in a direction of an arrow A shown in FIG. 1. The in-vehicle radar device 1 receives radio waves in a direction opposite to the arrow A. The direction of the arrow A is a first direction described later. The first cover 2 is molded with a resin material such as PBT which allows radio waves to pass therethrough. The second cover 3 is also molded with a resin material. The heat sink 4 is molded with an aluminum die-cast material.

As shown in FIG. 2, the heat sink 4 includes a plate-shaped portion 4a formed in a flat-plate shape. The normal direction of one surface of the plate-shaped portion 4a is defined as the first direction, and the normal direction of another surface of the plate-shaped portion 4a is defined as a second direction. The heat sink 4 further includes a side portion 4b surrounding the periphery of the plate-shaped portion 4a and protruding in the first direction and the second direction relative to the plate-shaped portion 4a. The first cover 2 covers the first-direction side of the heat sink 4, and the second cover 3 covers the second-direction side of the heat sink 4. The first cover 2 or the second cover 3 is provided with posts 3a standing at the surface on the heat sink 4 side of the first cover 2 or the second cover 3. In the present embodiment, four posts 3a are formed through integral molding at corners of the second cover 3. The number, the formation positions, and the formation method of the posts 3a are not limited to the above ones, and two posts may be formed by adhesion on the first cover 2.

Each post 3a penetrates through a through hole 4c provided in the side portion 4b of the heat sink 4. The first cover 2 and the second cover 3 are connected via the posts 3a. As shown in FIG. 4, a part where the first cover 2 and the second cover 3 are connected is a connection portion 3a1 of the post 3a. The first cover 2 not having the posts 3a, and the posts 3a, are connected by heat welding, thermal caulking, or snap-fit. In FIG. 4, the posts 3a and the first cover 2 are connected by thermal caulking, but they may be connected by another method. Thermal welding is a method of applying heat to a connection part by ultrasound, vibration, or a laser beam to melt connection part members and connect them. Thermal caulking is a method of providing a communication hole in one part, inserting the tip of the post 3a provided at another part into the communication hole so that the tip protrudes therefrom, and melting the protruding tip by a heater, to form a caulked portion and connect them. Snap-fit is a method of providing the tip of the post 3a with a nail to be caught on a counterpart member and thereby engaging the post 3a with a communication hole of the counterpart member. In a case where waterproof property is required in view of the equipment environment of the in-vehicle radar device 1, the interfaces between the first cover 2, the second cover 3, and the heat sink 4 may be filled with a seal material such as a silicon adhesive, so as to ensure waterproof property of the in-vehicle radar device 1. The positions where the through holes 4c are provided are not limited to the side portion 4b.

Since the first cover 2 and the second cover 3 are connected as described above, another special component is not needed for connection therebetween, so that the number of components of the in-vehicle radar device 1 can be decreased. In addition, since they are connected by heat welding, thermal caulking, or snap-fit, the number of components of the in-vehicle radar device 1 can be decreased and workability in assembling of the in-vehicle radar device 1 can be improved.

As shown in FIG. 2, the in-vehicle radar device 1 includes the first circuit board 6 and a conductive inner cover 5. The first circuit board 6 includes a plate-shaped first board 6a, a first electronic component 6b and a first ground pattern 6c (not shown in FIG. 2) provided at one or both of the surface on the first-direction side and the surface on the second-direction side of the first board 6a, and a plate-shaped antenna portion 6d formed at the surface on the first-direction side of the first board 6a. The first board 6a is formed by, for example, epoxy-based resin. In FIG. 2, the first electronic component 6b is located at the surface on the first-direction side of the first board 6a. The inner cover 5 is formed in a plate shape, and has a through portion 5a at a part opposed to the antenna portion 6d.

As shown in FIG. 4, the first circuit board 6 is stored in the first space 10, such that the surface on the second-direction side of the first board 6a contacts with the heat sink 4. In FIG. 4, the first electronic component 6b is not shown. The first board 6a may have, in an inner layer of the first board 6a, a solid pattern 6a1 formed over a wide area or the entire area and connected to the first ground pattern 6c at the surface. Forming the solid pattern 6a1 can increase the shield performance of the in-vehicle radar device 1 against unnecessary radio waves. The inner cover 5 is also stored in the first space 10, such that the surface thereof on the first-direction side contacts with the first cover 2 and the surface thereof on the second-direction side contacts with at least a part of the surface on the first-direction side of the first circuit board 6. The inner cover is manufactured through molding with a PC resin material containing a conductive material such as a carbon fiber, or the like.

<Elastic Members 8>

The in-vehicle radar device 1 includes elastic members 8 fixed to the first-direction side of the second cover 3. The elastic members 8 are compressed between the second cover 3 and the heat sink 4, and press the heat sink 4, the first circuit board 6, and the inner cover 5 to the first cover 2, so that the first circuit board 6 is held between the heat sink 4 and the inner cover 5. The elastic members 8 are molded with a rubber material, for example. The elastic members 8 may be made of a heat-resistant silicon material of which change in load based on compression is small with respect to the environmental temperature. The elastic members 8 may be fixed by being press-fitted into the second cover 3 or may be provided through in-mold processing. It is noted that, by changing the hardness of the elastic member 8, it is possible to change the pressing force. Here, in view of variations in components and expansion/contraction of components due to the environmental temperature, a hardness (Asker C) of 40 degrees is selected as the hardness of the elastic member 8 that can keep the contact states of the members. However, the hardness of the elastic member 8 is not limited thereto.

The first ground pattern 6c of the first circuit board 6 contacts with and is electrically connected to one or both of the heat sink 4 and the inner cover 5. In FIG. 4, the first ground patterns 6c contact with both of the heat sink 4 and the inner cover 5. The inner cover 5 is held between the first circuit board 6 and the first cover 2. The distance between the antenna portion 6d and the first cover 2 is equal to the thickness of the inner cover 5 at the parts contacting with the first circuit board 6 and the first cover 2. By changing the thickness of the inner cover 5, it is possible to change the distance between the inner surface of the first cover 2 and the antenna portion 6d on the first board 6a.

With this structure, when a component composing the in-vehicle radar device 1 has dimension variations and/or expands/contracts due to temperature change, dimension change of the component is absorbed by the compression allowances of the elastic members 8, whereby it is possible to keep continuous pressing between the first ground pattern 6c of the first circuit board 6 and the conductive inner cover 5 or the conductive heat sink 4. Since continuous pressing is kept, stable electric connection of the first ground pattern 6c of the first circuit board 6 can be ensured. In a case where the elastic members 8 are made of a rubber material, the compression allowances of the elastic members 8 are increased, so that, when a component composing the in-vehicle radar device 1 has dimension variations and/or expands/contracts due to temperature change, the absorption allowance for dimension change of the component can be increased. In addition, since rubber components are used as the elastic members 8, a force for attenuating vibration applied to each elastic member 8 increases, whereby, in such a case where the device-equipped vehicle travels on a rough road, vibration transferring from a road surface to the first circuit board 6, the inner cover 5, and the heat sink 4 can be suppressed. Thus, it is possible to more assuredly press the first ground pattern 6c of the first circuit board 6 and the conductive inner cover 5 or the conductive heat sink 4 with each other, whereby it is possible to provide the in-vehicle radar device 1 in which stable electric connection of the first ground pattern 6c of the first circuit board 6 is ensured.

In addition, since the distance between the antenna portion 6d and the first cover 2 is equal to the thickness of the inner cover 5 held between the first cover 2 and the first circuit board 6, a plurality of components are not present between the antenna portion 6d and the first cover 2, and therefore desired radar performance can be obtained with dimension management of a small number of components. In addition, when a component composing the in-vehicle radar device 1 has dimension variations and/or expands/contracts due to temperature change, dimension change of the component is absorbed by the compression allowances of the elastic members 8, whereby the state in which the inner cover 5 is held between the first cover 2 and the first circuit board 6 can be kept constantly. Therefore, the distance between the antenna portion 6d and the first cover 2 is stably kept, so that the radar performance can be uniformed and stabilized among products. Thus, since the state in which the inner cover 5 is held between the first cover 2 and the first circuit board 6 is assuredly kept and therefore the distance between the antenna portion 6d and the first cover 2 is stably kept, it is possible to provide the in-vehicle radar device 1 in which the radar performance is stabilized.

In addition, since a plurality of components such as screws are not used for directly pressing the first ground pattern 6c of the first circuit board 6 and the conductive inner cover 5 or the conductive heat sink 4 with each other, the in-vehicle radar device 1 can be assembled with a small number of components. In addition, since processes such as screw torque management are not needed, workability in assembling of the in-vehicle radar device 1 is improved, whereby productivity of the in-vehicle radar device 1 can be improved.

<First Ground Pattern 6c>

Modifications of the first ground pattern 6c will be described with reference to FIG. 5 to FIG. 8. Since the heat sink 4 and the inner cover 5 are members having conductivity, they are hereafter referred to as conductive members. A contact portion 6c1 which is a part contacting with one or both of the heat sink 4 and the inner cover 5, on the first ground pattern 6c, is formed along the outer periphery of the first board 6a. FIG. 5 is a plan view on the first-direction side of the first circuit board 6. The contact portion 6c1 is included within the area of the first ground pattern 6c, and contacts with and is electrically connected to the inner cover 5. In a case where the first ground pattern 6c is provided on the second-direction side of the first circuit board 6, the contact portion 6c1 contacts with the heat sink 4. In FIG. 4, the contact portions 6c1 are provided on both of the heat sink 4 side and the inner cover 5 side. Since the contact portions 6c1 are formed along the outer periphery of the first board 6a, a shield for the first electronic components 6b provided to the first board 6a against unnecessary radio waves from outside can be formed such that the first electronic components 6b are collectively enclosed by the contact portions 6c1 and the conductive members. Since the shield is formed by the contact portions 6c1 and the conductive members, the number of components is not increased, and therefore productivity of the in-vehicle radar device 1 is not lowered. As compared to a case of providing a shield as a separate component, productivity of the in-vehicle radar device 1 can be improved.

A contact portion 6c2 which is a part contacting with one or both of the heat sink 4 and the inner cover 5, on the first ground pattern 6c, is formed so as to surround at least one first electronic component 6b. FIG. 6 is a plan view on the first-direction side of the first circuit board 6. The contact portion 6c2 is included within the area of the first ground pattern 6c, and contacts with and is electrically connected to the inner cover 5. In a case where the first electronic component 6b is provided on the second-direction side of the first circuit board 6, the first ground pattern 6c is also provided on the second-direction side of the first circuit board 6, and the contact portion 6c2 contacts with and is electrically connected to the heat sink 4. Since the contact portion 6c2 is formed so as to surround the first electronic component 6b, a shield for the first electronic component 6b provided to the first board 6a against unnecessary radio waves from outside can be formed such that the first electronic component 6b is enclosed by the contact portion 6c2 and the conductive members. Since the shield is formed by the contact portion 6c2 and the conductive members, the number of components is not increased, and therefore productivity of the in-vehicle radar device 1 is not lowered. In addition, in the shield enclosing the first electronic component 6b individually, the contact area of the first ground pattern 6c is provided in a limited manner, whereby the influence of warp of the contact portions between the first circuit board 6, and the inner cover 5 and the heat sink 4, is reduced, so that stable conductivity between respective contact parts can be obtained. Thus, a manufacturing process such as component working or inspection relevant to management of warp amounts of components can be simplified.

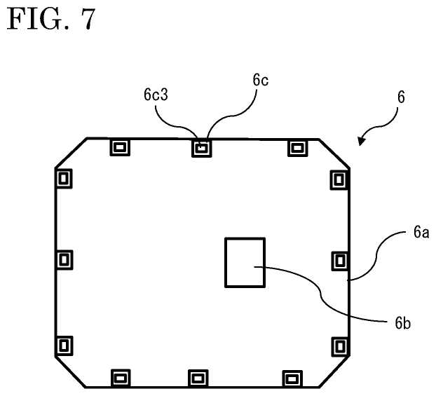

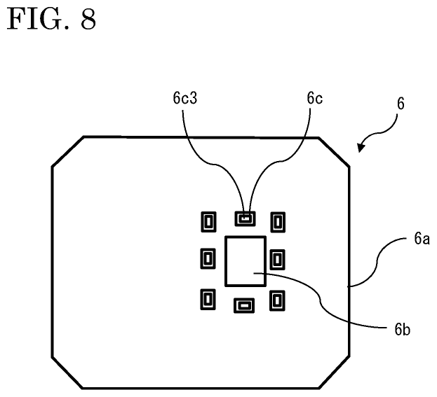

Contact portions 6c3 which are the parts contacting with one or both of the heat sink 4 and the inner cover 5, on the first ground pattern 6c, are formed at a plurality of locations arranged with an interval therebetween. FIG. 7 is a plan view on the first-direction side of the first circuit board 6. The contact portions 6c3 are formed along the outer periphery of the first board 6a and are each included within the area of the first ground pattern 6c. The contact portions 6c3 contact with and are electrically connected to the inner cover 5. FIG. 8 is a plan view on the first-direction side of the first circuit board 6. The contact portions 6c3 surround the first electronic component 6b and are each included within the area of the first ground pattern 6c. The contact portions 6c3 contact with and are electrically connected to the inner cover 5. The contact portions 6c3 may be provided on the second-direction side of the first circuit board 6. Since the contact portions 6c3 are formed as partial areas at a plurality of locations arranged with an interval therebetween, the contact area of the first ground pattern 6c can be further limited, whereby the manufacturing process for the in-vehicle radar device 1 can be simplified. In addition, the heights of the contact areas at the parts on the inner cover 5 side and the heat sink 4 side can be finely adjusted in accordance with variations in the thickness of the first circuit board 6, slight warp thereof, and the like, whereby stable conductivity and shield property can be obtained at the ground contact parts.

If the interval between the contact portions 6c3 is set to an interval according to the wavelength of unnecessary radio waves assumed in the equipment environment of the in-vehicle radar device 1, entry of unnecessary radio waves into the first ground pattern 6c can be suppressed. In the present embodiment, in view of ¼ of a wavelength 100 mm for 3 GHz at maximum, the interval between the contact portions 6c3 which is the interval between the parts of the first ground pattern 6c arranged at the plurality of locations is set to not greater than 25 mm. Although the interval between the contact portions 6c3 is set to not greater than 25 mm, the interval may be expanded in accordance with the frequency that is a shielding target, whereby the influence of warp of the first circuit board 6 is reduced and stable electric connection is obtained owing to more assured contact. By arranging the contact portions 6c3 with an interval according to the wavelength of unnecessary radio waves from outside, it is possible to prevent unnecessary radio waves in a desired frequency band from entering through the interval between the contact portions 6c3. In a case where the interval is set to not greater than 25 mm, the interval can be a length of not greater than ¼ of the maximum wavelength 100 mm within 3 GHz under the assumption of the in-vehicle environment, whereby entry of unnecessary radio waves in this frequency range can be suppressed.

FIG. 9 is a sectional view of the in-vehicle radar device 1 including the first circuit board 6 shown in FIG. 7. At least one of the contact portions 6c3 which are the parts of the first ground pattern 6c arranged at the plurality of locations, and respective parts of the first cover 2, the inner cover 5, the first circuit board 6, the heat sink 4, and the second cover 3, overlap each other as seen in the normal direction of the plate-shaped portion 4a. The overlapping located parts contact with each other by pressing forces of the elastic members 8. In FIG. 9, the normal directions at the overlapping located parts are indicated by dotted-dashed lines. Reaction forces based on compression of the elastic members 8 are directly transferred to the respective overlapping located parts, so that the contact pressures are increased, whereby electric conduction between the first ground pattern 6c of the first circuit board 6 and the conductive member is ensured. Since the respective parts are pressed by the elastic members 8 as described above, loads are directly transferred between the respective contact parts, whereby the contact pressures are increased and variations in the contact pressures can be reduced. In addition, the contact resistance of the contact portion 6c3 of the first ground pattern 6c is reduced, whereby stable conductivity and shield property can be obtained.

The rigidities of the first board 6a and the inner cover 5 are lower than the rigidities of the heat sink 4 and the first cover 2. The first board 6a and the inner cover 5 are provided between the heat sink 4 and the first cover 2, and contact with them so as to be held therebetween. The first board 6a and the inner cover 5 follow the higher-rigidity-part sides and electric conduction between the first ground pattern 6c and the conductive member is ensured. The thicknesses of respective parts of the first board 6a, the inner cover 5, the heat sink 4, and the first cover 2 may be increased/decreased or ribs may be provided to these parts, thereby forming such a rigidity relationship as to follow the higher-rigidity-part sides. With this rigidity relationship, when the first board 6a and the inner cover 5 are pressed by reaction forces based on compression of the elastic members 8, the first board 6a and the inner cover 5 are deflected to follow the heat sink 4 and the first cover 2 having higher rigidities, whereby warp and thickness variations at the parts of the first board 6a held therebetween can be absorbed and thus it is possible to obtain the in-vehicle radar device 1 in which stable electric connection and shield property are ensured for the first ground pattern 6c.

The first ground patterns 6c may be provided at both of the surface on the first-direction side and the surface on the second-direction side of the first board 6a. The first ground pattern 6c provided at the surface on the first-direction side of the first board 6a contacts with and is electrically connected with the inner cover 5. The first ground pattern 6c provided at the surface on the second-direction side of the first board 6a contacts with and is electrically connected to the heat sink 4. With this structure, electric connection of the first ground patterns 6c at both surfaces of the first circuit board 6 can be ensured. In addition, both of desired first electronic components 6b mounted at both surfaces of the first circuit board 6 can be shielded. In addition, the in-vehicle radar device 1 can be assembled with a small number of components, and workability in assembling of the in-vehicle radar device 1 is improved, whereby productivity of the in-vehicle radar device 1 can be improved.

As described above, the in-vehicle radar device 1 according to embodiment 1 includes the elastic member fixed to the first-direction side of the second cover 3, and pressing the heat sink 4, the first circuit board 6, and the inner cover 5 to the first cover 2, so that the first circuit board 6 is held between the heat sink 4 and the inner cover 5, and the first ground pattern 6c of the first circuit board 6 is pressed by the elastic member 8 so as to contact with and be electrically connected to one or both of the conductive heat sink 4 and the conductive inner cover 5. Thus, it is possible to easily ensure stable electric connection between the first ground pattern 6c of the first circuit board 6 and the member having conductivity. In addition, since the distance between the antenna portion 6d and the first cover 2 is equal to the thickness of the inner cover 5 pressed by the elastic member 8, variations in accuracy of the distance between the antenna portion 6d and the first cover 2 are reduced, and the distance between the antenna portion 6d and the first cover 2 does not readily change. Thus, variations in the radar performance of the in-vehicle radar device 1 can be reduced.

The elastic member 8 may be a rubber material. Thus, the compression allowance of the elastic member 8 is increased, and when a component composing the in-vehicle radar device 1 has dimension variations and/or expands/contracts due to temperature change, the absorption allowance for dimension change of the component can be increased. The contact portion 6c1 which is a part contacting with one or both of the heat sink 4 and the inner cover 5, on the first ground pattern 6c, may be formed along the outer periphery of the first board 6a. Thus, a shield for the first electronic components 6b provided to the first board 6a against unnecessary radio waves from outside can be formed such that the first electronic components 6b are collectively enclosed by the contact portion 6c1 and the conductive members. The contact portion 6c2 which is a part contacting with one or both of the heat sink 4 and the inner cover 5, on the first ground pattern 6c, may be formed so as to surround at least one first electronic component 6b. Thus, a shield for the first electronic component 6b provided to the first board 6a against unnecessary radio waves from outside can be formed such that the first electronic component 6b is enclosed by the contact portion 6c2 and the conductive members. In addition, in the shield enclosing the first electronic component 6b individually, the contact area of the first ground pattern 6c is provided in a limited manner, whereby the influence of warp of the contact portions between the first circuit board 6, and the inner cover 5 and the heat sink 4, is reduced, so that stable conductivity between respective contact parts can be obtained.

The contact portions 6c3 which are the parts contacting with one or both of the heat sink 4 and the inner cover 5, on the first ground pattern 6c, may be formed at a plurality of locations arranged with an interval therebetween. Thus, the contact area of the first ground pattern 6c can be limited, whereby the manufacturing process for the in-vehicle radar device 1 can be simplified. The interval between the parts of the first ground pattern 6c arranged at the plurality of locations may be set to not greater than 25 mm. Thus, if the interval is set to an interval according to the wavelength of unnecessary radio waves assumed in the equipment environment of the in-vehicle radar device 1 (here, ¼ of a wavelength 100 mm for 3 GHz at maximum), entry of unnecessary radio waves into the first ground pattern 6c can be suppressed.

At least one of the contact portions 6c3 which are the parts of the first ground pattern 6c arranged at the plurality of locations, and respective parts of the first cover 2, the inner cover 5, the first circuit board 6, the heat sink 4, and the second cover 3, may overlap each other as seen in the normal direction of the plate-shaped portion 4a, and the overlapping located parts may contact with each other by a pressing force of the elastic member 8. Thus, a reaction force based on compression of the elastic member 8 is directly transferred to the respective overlapping located parts, so that the contact pressures are increased, whereby electric conduction between the first ground pattern 6c of the first circuit board 6 and the conductive member can be stably ensured. Rigidities of the first board 6a and the inner cover 5 may be lower than rigidities of the heat sink 4 and the first cover 2. Thus, when the first board 6a and the inner cover 5 are pressed by a reaction force based on compression of the elastic member 8, the first board 6a and the inner cover 5 are deflected to follow the heat sink 4 and the first cover 2 having higher rigidities, whereby warp and thickness variations at the parts of the first board 6a held therebetween can be absorbed and thus electric conduction between the first ground pattern 6c of the first circuit board 6 and the conductive member can be stably ensured.

The first ground patterns 6c may be provided at both of the surface on the first-direction side and the surface on the second-direction side of the first board 6a, the first ground pattern 6c provided at the surface on the first-direction side of the first board 6a may contact with and be electrically connected to the inner cover 5, and the first ground pattern 6c provided at the surface on the second-direction side of the first board 6a may contact with and be electrically connected to the heat sink 4. Thus, electric connection of the first ground patterns 6c at both surfaces of the first circuit board 6 can be ensured, and both of desired first electronic components 6b mounted at both surfaces of the first circuit board 6 can be shielded.

### Embodiment 2

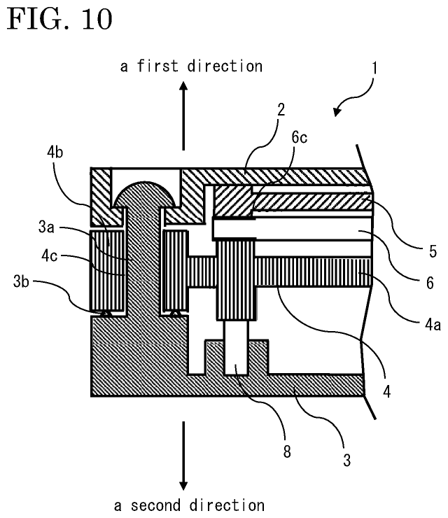

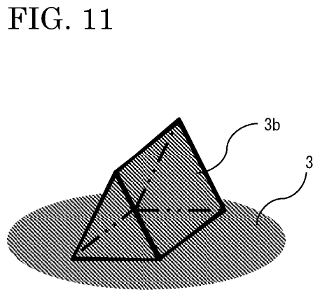

The in-vehicle radar device 1 according to embodiment 2 will be described. FIG. 10 is a major part sectional view of the in-vehicle radar device 1 according to embodiment 2. FIG. 11 is a perspective view showing a protrusion 3b of the in-vehicle radar device 1. The in-vehicle radar device 1 according to embodiment 2 is provided with the protrusions 3b in addition to the structure in embodiment 1.

As shown in FIG. 10, the second cover 3 has, around the post 3a, the protrusions 3b protruding toward the first-direction side and contacting with the side portion 4b of the heat sink 4. Each protrusion 3b is molded integrally with the second cover 3. As shown in FIG. 11, the protrusion 3b is formed in a triangular prism shape having a triangular cross-section. By a reaction force based on compression of the protrusion 3b, the protrusion 3b presses the heat sink 4, the first circuit board 6, and the inner cover 5 to the first cover 2. The locations, the number, and the shapes of the protrusions 3b are not limited to the above ones. However, employing such a triangular shape with a pointed tip can increase the compression allowance. Since the protrusion 3b having a triangular prism shape is compressed, dimension variations of components are absorbed, and also the slope of the reaction force with respect to the compression amount is reduced, whereby a stable reaction force can be obtained. The part of the heat sink 4 with which the protrusion 3b contacts is not limited to the side portion 4b.

As described above, in the in-vehicle radar device 1 according to embodiment 2, the protrusion 3b of the second cover 3 presses the heat sink 4, the first circuit board 6, and the inner cover 5 to the first cover 2, whereby it is possible to press the members to the first cover 2 in addition to the load to press the members through compression of the elastic member 8. Thus, when the in-vehicle radar device 1 experiences excessive vibration acceleration occurring in such a case where the vehicle equipped with the in-vehicle radar device 1 travels on a rough road, the positional relationship between the antenna portion 6d and the first cover 2 can be more stably kept, whereby the radar performance can be stabilized. In addition, stable electric connection and shield property between the first ground pattern 6c of the first circuit board 6 and the conductive member can be further enhanced.

### Embodiment 3

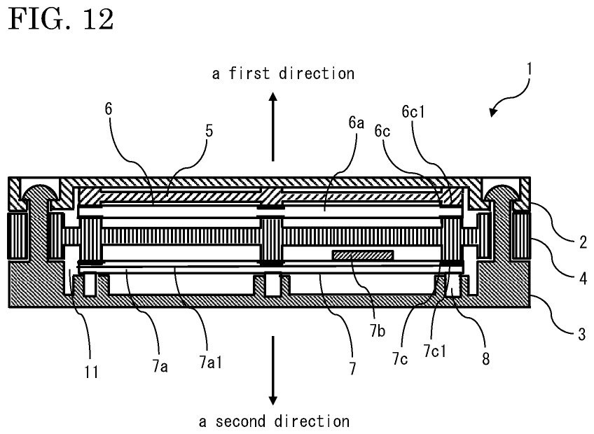

The in-vehicle radar device 1 according to embodiment 3 will be described. FIG. 12 is a sectional view of the in-vehicle radar device 1 according to embodiment 3. FIG. 12 is a sectional view of the in-vehicle radar device 1 taken at a position equivalent to the A-A cross-section position in FIG. 3. The in-vehicle radar device 1 according to embodiment 3 is provided with a second circuit board 7 in addition to the structure in embodiment 1.

As shown in FIG. 12, the in-vehicle radar device 1 includes the second circuit board 7. The second circuit board 7 includes a plate-shaped second board 7a, and a second electronic component 7b and a second ground pattern 7c provided at the surface on the first-direction side of the second board 7a. The second circuit board 7 is stored in a second space 11 formed between the heat sink 4 and the second cover 3. The surface on the first-direction side of the second board 7a of the second circuit board 7 contacts with the heat sink 4. The elastic members 8 press the second circuit board 7, the heat sink 4, the first circuit board 6, and the inner cover 5 to the first cover 2, so that the second circuit board 7 is held between the heat sink 4 and the elastic members 8. The second ground pattern 7c of the second circuit board 7 contacts with and is electrically connected to the heat sink 4.

The second board 7a is formed by, for example, epoxy-based resin. The second board 7a has, in an inner layer of the second board 7a, a solid pattern 7a1 formed over a wide area or the entire area and connected to the second ground pattern 7c at the surface. Forming the solid pattern 7a1 can increase the shield performance of the in-vehicle radar device 1 against unnecessary radio waves.

A contact portion 7c1 which is a part contacting with the heat sink 4, on the second ground pattern 7c, may be formed so as to surround at least one second electronic component 7b. The contact portions 7c1 which are the parts contacting with the heat sink 4, on the second ground pattern 7c, may be formed at a plurality of locations arranged with an interval therebetween. The interval between the contact portions 7c1 which are the parts of the second ground pattern 7c arranged at the plurality of locations may be set to not greater than 25 mm.

As described above, in the in-vehicle radar device 1 according to embodiment 3, the surface on the first-direction side of the second board 7a of the second circuit board 7 contacts with the heat sink 4, the elastic member 8 presses the second circuit board 7, the heat sink 4, the first circuit board 6, and the inner cover 5 to the first cover 2, and the second ground pattern 7c of the second circuit board 7 contacts with and is electrically connected to the heat sink 4. Thus, it is possible to easily ensure stable electric connection between, as well as the first ground pattern 6c of the first circuit board 6, the second ground pattern 7c of the second circuit board 7 and the member having conductivity.

The contact portion 7c1 which is the part contacting with the heat sink 4, on the second ground pattern 7c, may be formed so as to surround at least one second electronic component 7b. Thus, a shield for the second electronic component 7b provided to the second board 7a against unnecessary radio waves from outside can be formed such that the second electronic component 7b is enclosed by the contact portion 7c1 and the conductive members. In addition, in the shield enclosing the second electronic component 7b individually, the contact area of the second ground pattern 7c is provided in a limited manner, whereby the influence of warp of the contact portion between the second circuit board 7 and the heat sink 4 is reduced, so that stable conductivity between respective contact parts can be obtained.

The contact portions 7c1 which are the parts contacting with the heat sink 4, on the second ground pattern 7c, may be formed at a plurality of locations arranged with an interval therebetween. Thus, the contact area of the second ground pattern 7c can be limited, whereby the manufacturing process for the in-vehicle radar device 1 can be simplified. The interval between the parts of the second ground pattern 7c arranged at the plurality of locations may be set to not greater than 25 mm. Thus, if the interval is set to an interval according to the wavelength of unnecessary radio waves assumed in the equipment environment of the in-vehicle radar device 1 (here, ¼ of a wavelength 100 mm for 3 GHz at maximum), entry of unnecessary radio waves into the second ground pattern 7c can be suppressed.

### Embodiment 4

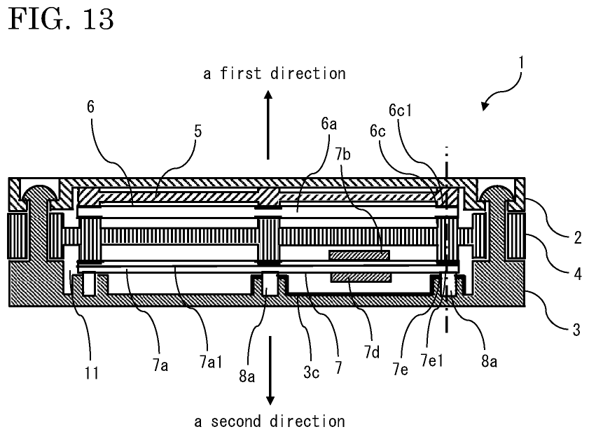

The in-vehicle radar device 1 according to embodiment 4 will be described. FIG. 13 is a sectional view of the in-vehicle radar device 1 according to embodiment 4. FIG. 13 is a sectional view of the in-vehicle radar device 1 taken at a position equivalent to the A-A cross-section position in FIG. 3. The in-vehicle radar device 1 according to embodiment 4 is provided with a third electronic component 7d and a third ground pattern 7e at the second circuit board 7, in addition to the structure in embodiment 3.

The second circuit board 7 includes at least one third electronic component 7d and the third ground pattern 7e provided at the surface on the second-direction side of the second board 7a. A conductive pattern 3c is formed at a part of the second cover 3 that is opposed to at least one third electronic component 7d. The third ground pattern 7e and the conductive pattern 3c are electrically connected via a conductive elastic member 8a which is the elastic member 8 having conductivity. The conductive elastic member 8a is molded with a silicon rubber material containing a conductive metal component such as carbon, for example. The conductive pattern 3c may be formed by plating with copper and nickel on the inner surface of the second cover 3, or may be formed by fixing, by thermal caulking, sheet metal made of metal such as an aluminum material to a projection provided to the second cover 3.

A contact portion 7e1 which is a part contacting with the conductive elastic member 8a, on the third ground pattern 7e, may be formed so as to surround at least one third electronic component 7d. The contact portions 7e1 which are the parts contacting with the conductive elastic member 8a, on the third ground pattern 7e, may be formed at a plurality of locations arranged with an interval therebetween. The interval between the contact portions 7e1 which are the parts of the third ground pattern 7e arranged at the plurality of locations may be set to not greater than 25 mm.

At least one of the contact portions 7e1 which are the parts of the third ground pattern 7e arranged at the plurality of locations, and respective parts of the heat sink 4, the second circuit board 7, and the conductive elastic member 8a, overlap each other as seen in the normal direction of the plate-shaped portion 4a. The overlapping located parts contact with each other by a pressing force of the conductive elastic member 8a. In FIG. 13, the normal direction at the overlapping located parts is indicated by a dotted-dashed line. A reaction force based on compression of the conductive elastic member 8a is directly transferred to the respective overlapping located parts, so that the contact pressures are increased, whereby electric conduction between the third ground pattern 7e of the second circuit board 7 and the conductive member is ensured.

As described above, in the in-vehicle radar device 1 according to embodiment 4, the conductive pattern 3c is formed at the part of the second cover 3 that is opposed to at least one third electronic component 7d, and the third ground pattern 7e and the conductive pattern 3c are electrically connected via the conductive elastic member 8a. Thus, it is possible to easily ensure stable electric connection between the third ground pattern 7e on the second-direction side of the second circuit board 7 and the conductive pattern 3c of the second cover 3.

The contact portion 7e1 which is a part contacting with the conductive elastic member 8a, on the third ground pattern 7e, may be formed so as to surround at least one third electronic component 7d. Thus, a shield for the third electronic component 7d provided to the second board 7a against unnecessary radio waves from outside can be formed such that the third electronic component 7d is enclosed by the contact portion 7e1 and the conductive pattern 3c. In addition, in the shield enclosing the third electronic component 7d individually, the contact area of the third ground pattern 7e is provided in a limited manner, whereby the influence of warp of the contact portion between the second circuit board 7 and the conductive elastic member 8a is reduced, so that stable conductivity between respective contact parts can be obtained.

The contact portions 7e1 which are the parts contacting with the conductive elastic member 8a, on the third ground pattern 7e, may be formed at a plurality of locations arranged with an interval therebetween. Thus, the contact area of the third ground pattern 7e can be limited, whereby the manufacturing process for the in-vehicle radar device 1 can be simplified. The interval between the parts of the third ground pattern 7e arranged at the plurality of locations may be set to not greater than 25 mm. Thus, if the interval is set to an interval according to the wavelength of unnecessary radio waves assumed in the equipment environment of the in-vehicle radar device 1 (here, ¼ of a wavelength 100 mm for 3 GHz at maximum), entry of unnecessary radio waves into the third ground pattern 7e can be suppressed.

At least one of the contact portions 7e1 which are the parts of the third ground pattern 7e arranged at the plurality of locations, and respective parts of the heat sink 4, the second circuit board 7, and the conductive elastic member 8a, may overlap each other as seen in the normal direction of the plate-shaped portion 4a, and the overlapping located parts may contact with each other by a pressing force of the conductive elastic member 8a. Thus, a reaction force based on compression of the conductive elastic member 8a is directly transferred to the respective overlapping located parts, so that the contact pressures are increased, whereby variations in the contact pressures can be reduced. In addition, electric conduction between the third ground pattern 7e of the second circuit board 7 and the conductive member can be stably ensured. In addition, the contact resistance of the contact portion 7e1 of the third ground pattern 7e is reduced, whereby stable conductivity and shield property can be obtained.

### Embodiment 5

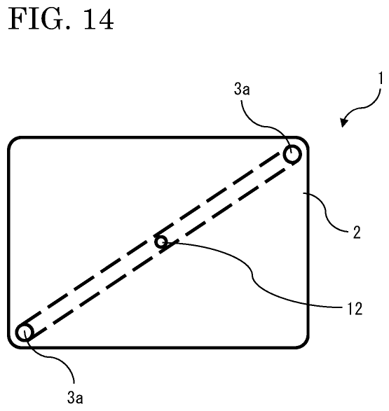

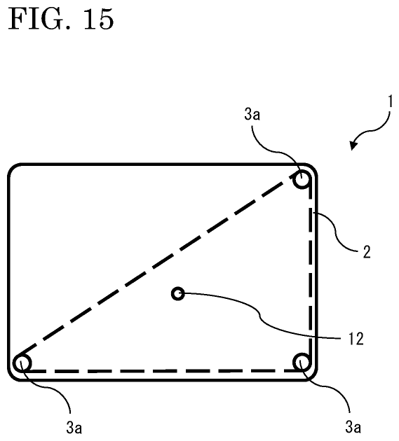

The in-vehicle radar device 1 according to embodiment 5 will be described. FIG. 14 is a plan view on the first cover 2 side of the in-vehicle radar device 1 according to embodiment 5. FIG. 15 is a plan view on the first cover 2 side of another in-vehicle radar device 1 according to embodiment 5. In the in-vehicle radar device 1 according to embodiment 5, the location of a center of gravity 12 is prescribed.

In the in-vehicle radar device 1, a plurality of posts 3a are provided. In FIG. 14, two posts 3a are provided, and in FIG. 15, three posts 3a are provided. The center of gravity 12 of a member held between the first cover 2 and the second cover 3 is located in an area surrounded by the plurality of posts 3a. In FIG. 14 and FIG. 15, an area surrounded by a broken line is the area surrounded by the plurality of posts 3a, and a location indicated by a circle is the center of gravity 12 of the member held between the above two covers.

As described above, in the in-vehicle radar device 1 according to embodiment 5, the center of gravity 12 of the member held between the first cover 2 and the second cover 3 is located in the area surrounded by the plurality of posts 3a, whereby the center of gravity 12 can be located in the area surrounded by the plurality of posts 3a for which a high rigidity is ensured. Thus, when the in-vehicle radar device 1 experiences excessive vibration occurring in such a case where the vehicle equipped with the in-vehicle radar device 1 travels on a rough road, and a load corresponding to the vibration acceleration is applied at the position of the center of gravity, the load can be received in the higher-rigidity area, whereby positional displacement between the antenna portion 6d and the first cover 2 can be prevented. Since positional displacement between the antenna portion 6d and the first cover 2 is prevented, the radar performance of the in-vehicle radar device 1 can be stabilized. In addition, stable electric connection and shield property can be ensured for the first ground pattern 6c of the first circuit board 6. In addition, by decreasing the number of the posts 3a, the member structures are simplified, whereby the manufacturing process can be simplified.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 in-vehicle radar device
2 first cover
3 second cover
3a post
3a1 connection portion
3b protrusion
3c conductive pattern
4 heat sink
4a plate-shaped portion
4b side portion
4c through hole
5 inner cover
5a through portion
6 first circuit board
6a first board
6a1 solid pattern
6b first electronic component
6c first ground pattern
6c1 contact portion
6d antenna portion
7 second circuit board
7a second board
7a1 solid pattern
7b second electronic component
7c second ground pattern
7c1 contact portion
7d third electronic component
7e third ground pattern
7e1 contact portion
8 elastic member
8a conductive elastic member
10 first space
11 second space
12 center of gravity

1. An in-vehicle radar device comprising:
a conductive heat sink which includes a plate-shaped portion formed in a flat-plate shape, and of which an outer peripheral surface is at least partially exposed to outside;
a first cover which allows radio waves to pass therethrough, where a normal direction of one surface of the plate-shaped portion is defined as a first direction and a normal direction of another surface of the plate-shaped portion is defined as a second direction, the first cover covering the first-direction side of the heat sink;
a second cover covering the second-direction side of the heat sink and connected to the first cover;
a first circuit board including a plate-shaped first board, a first electronic component and a first ground pattern provided at one or both of a surface on the first-direction side and a surface on the second-direction side of the first board, and a plate-shaped antenna portion formed at the surface on the first-direction side of the first board, the first circuit board being stored in a first space formed between the heat sink and the first cover, such that the surface on the second-direction side of the first board contacts with the heat sink;
a conductive inner cover formed in a plate shape and having a through portion at a part opposed to the antenna portion, the inner cover being stored in the first space, such that a surface thereof on the first-direction side contacts with the first cover and a surface thereof on the second-direction side contacts with at least a part of the surface on the first-direction side of the first circuit board; and
an elastic member fixed to the first-direction side of the second cover and pressing the heat sink, the first circuit board, and the inner cover to the first cover, so that the first circuit board is held between the heat sink and the inner cover, wherein
the first ground pattern of the first circuit board contacts with and is electrically connected to one or both of the heat sink and the inner cover, and
a distance between the antenna portion and the first cover is equal to a thickness of the inner cover.

2. The in-vehicle radar device according to claim 1, wherein
the elastic member is a rubber material.

3. The in-vehicle radar device according to claim 1, wherein
a part contacting with one or both of the heat sink and the inner cover, on the first ground pattern, is formed along an outer periphery of the first board.

4. The in-vehicle radar device according to claim 1, wherein
a part contacting with one or both of the heat sink and the inner cover, on the first ground pattern, is formed so as to surround at least one said first electronic component.

5. The in-vehicle radar device according to claim 3, wherein
the parts contacting with one or both of the heat sink and the inner cover, on the first ground pattern, are formed at a plurality of locations arranged with an interval therebetween.

6. The in-vehicle radar device according to claim 5, wherein
the interval between the parts of the first ground pattern arranged at the plurality of locations is set to not greater than 25 mm.

7. The in-vehicle radar device according to claim 5, wherein
at least one of the parts of the first ground pattern arranged at the plurality of locations, and respective parts of the first cover, the inner cover, the first circuit board, the heat sink, and the second cover, overlap each other as seen in the normal direction of the plate-shaped portion, and
the overlapping located parts contact with each other by a pressing force of the elastic member.

8. The in-vehicle radar device according to claim 1, wherein
rigidities of the first board and the inner cover are lower than rigidities of the heat sink and the first cover.

9. The in-vehicle radar device according to claim 1, wherein
the first ground patterns are provided at both of the surface on the first-direction side and the surface on the second-direction side of the first board,
the first ground pattern provided at the surface on the first-direction side of the first board contacts with and is electrically connected to the inner cover, and
the first ground pattern provided at the surface on the second-direction side of the first board contacts with and is electrically connected to the heat sink.

10. The in-vehicle radar device according to claim 1, further comprising a second circuit board including a plate-shaped second board, and a second electronic component and a second ground pattern provided at a surface on the first-direction side of the second board, the second circuit board being stored in a second space formed between the heat sink and the second cover, such that the surface on the first-direction side of the second board contacts with the heat sink, wherein
the elastic member presses the second circuit board, the heat sink, the first circuit board, and the inner cover to the first cover, so that the second circuit board is held between the heat sink and the elastic member, and
the second ground pattern of the second circuit board contacts with and is electrically connected to the heat sink.

11. The in-vehicle radar device according to claim 10, wherein
the second circuit board includes at least one third electronic component and a third ground pattern provided at a surface on the second-direction side of the second board,
a conductive pattern is formed at a part of the second cover that is opposed to at least one said third electronic component, and
the third ground pattern and the conductive pattern are electrically connected via a conductive elastic member which is the elastic member having conductivity.

12. The in-vehicle radar device according to claim 10, wherein
a part contacting with the heat sink, on the second ground pattern, is formed so as to surround at least one said second electronic component.

13. The in-vehicle radar device according to claim 12, wherein
the parts contacting with the heat sink, on the second ground pattern, are formed at a plurality of locations arranged with an interval therebetween.

14. The in-vehicle radar device according to claim 13, wherein
the interval between the parts of the second ground pattern arranged at the plurality of locations is set to not greater than 25 mm.

15. The in-vehicle radar device according to claim 11, wherein
a part contacting with the conductive elastic member, on the third ground pattern, is formed so as to surround at least one said third electronic component.

16. The in-vehicle radar device according to claim 15, wherein
the parts contacting with the conductive elastic member, on the third ground pattern, are formed at a plurality of locations arranged with an interval therebetween.

17. The in-vehicle radar device according to claim 16, wherein
the interval between the parts of the third ground pattern arranged at the plurality of locations is set to not greater than 25 mm.

18. The in-vehicle radar device according to claim 16, wherein
at least one of the parts of the third ground pattern arranged at the plurality of locations, and respective parts of the heat sink, the second circuit board, and the conductive elastic member, overlap each other as seen in the normal direction of the plate-shaped portion, and
the overlapping located parts contact with each other by a pressing force of the conductive elastic member.

19. The in-vehicle radar device according to claim 1, wherein
the first cover or the second cover is provided with a post standing at a surface on the heat sink side of the first cover or the second cover,
the post penetrates through a through hole provided in the heat sink, and
the first cover and the second cover are connected via the post.

20. The in-vehicle radar device according to claim 19, wherein
the second cover has a protrusion protruding toward the first-direction side and contacting with the heat sink, and
the protrusion presses the heat sink, the first circuit board, and the inner cover to the first cover.

21. The in-vehicle radar device according to claim 19, wherein
a plurality of the posts are provided, and
a center of gravity of a member held between the first cover and the second cover is located in an area surrounded by the plurality of posts.

22. The in-vehicle radar device according to claim 19, wherein
the post that the first cover or the second cover has, and the first cover or the second cover not having the post, are connected by heat welding, thermal caulking, or snap-fit.
